(19) United States
(12) Patent Application Publication
(10) Pub. No.: US 2018/0269273 A1
(43) Pub. Date: Sep. 20, 2018

(54) INTERCONNECT STRUCTURES FOR A METAL-INSULATOR-METAL CAPACITOR

(71) Applicant: GLOBALFOUNDRIES Inc., Grand Cayman (KY)

(72) Inventors: Sunil Singh, Mechanicville, NY (US); Devender, Clifton Park, NY (US); Lili Cheng, Rexford, NY (US)

(21) Appl. No.: 15/463,011

(22) Filed: Mar. 20, 2017

(51) Int. Cl. H01L 49/02

(52) U.S. Cl. CPC H01L 28/60

(57) ABSTRACT

Methods for contacting a metal-insulator-metal (MIM) capacitor, as well as structures including a MIM capacitor. A dielectric layer is formed on an electrode of a metal-insulator-metal capacitor. A via is formed that extends vertically through the dielectric layer to the electrode. A conductive plug is formed in the via that contacts the electrode. The dielectric layer is comprised of a polymer, such as polyimide.

### BACKGROUND

The invention relates generally to semiconductor device fabrication and, in particular, to methods for contacting a metal-insulator-metal (MIM) capacitor and structures including a MIM capacitor.

On-chip passive elements, such as MIM capacitors, are deployed in many types of integrated circuits, such as radiofrequency integrated circuits. A MIM capacitor may be integrated into one or more of the metallization levels of a back-end-of-line (BEOL) interconnect structure using materials that are commonly available in copper BEOL technologies. A two-electrode MIM capacitor includes top and bottom conductive plates, which operate as electrodes, and an interplate dielectric layer disposed between the top and bottom conductive plates as an electrical insulator. The capacitance, or amount of charge held by the MIM capacitor per unit of applied voltage, depends among other factors on the area of the top and bottom conductive plates, their separation, and the dielectric constant of the material constituting the interplate dielectric layer.

Over-etch may be used during via formation to reliably guarantee penetration through etch stop layers incorporated into a device structure. A problem that may be encountered with a MIM capacitor is that, during the over-etching process, a via may penetrate completely through one or both of the conductive plates of the MIM capacitor. If such a punchthrough event occurs, then a circuit reliability problem or even a catastrophic failure may result. As via heights are scaled downwardly, the height difference among the multiple depth vias is reduced. As a result, the sensitivity of the passive elements to over-etch may be exacerbated and a MIM capacitor may be more susceptible to punchthrough events. The marginality of landing vias of smaller dimensons on the conductive plates may also lead to reductions in yield and reliability if one or both of the vias are misaligned.

Improved methods for contacting a MIM capacitor, as well as improved structures including a MIM capacitor, are needed.

### SUMMARY

In an embodiment of the invention, a structure includes a dielectric layer on an electrode of a metal-insulator-metal capacitor, and a conductive plug in a via that extends vertically through the dielectric layer to contact the electrode. The dielectric layer is comprised of a polymer, such as polyimide.

In an embodiment of the invention, a method includes forming a dielectric layer on an electrode of a metal-insulator-metal capacitor, and forming a via that extends vertically through the dielectric layer to the electrode. The method further includes forming a conductive plug in the via that contacts the electrode. The dielectric layer is comprised of a polymer, such as polyimide.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-4 are cross-sectional views of a device structure at successive fabrication stages of a processing method in accordance with embodiments of the invention.

### DETAILED DESCRIPTION

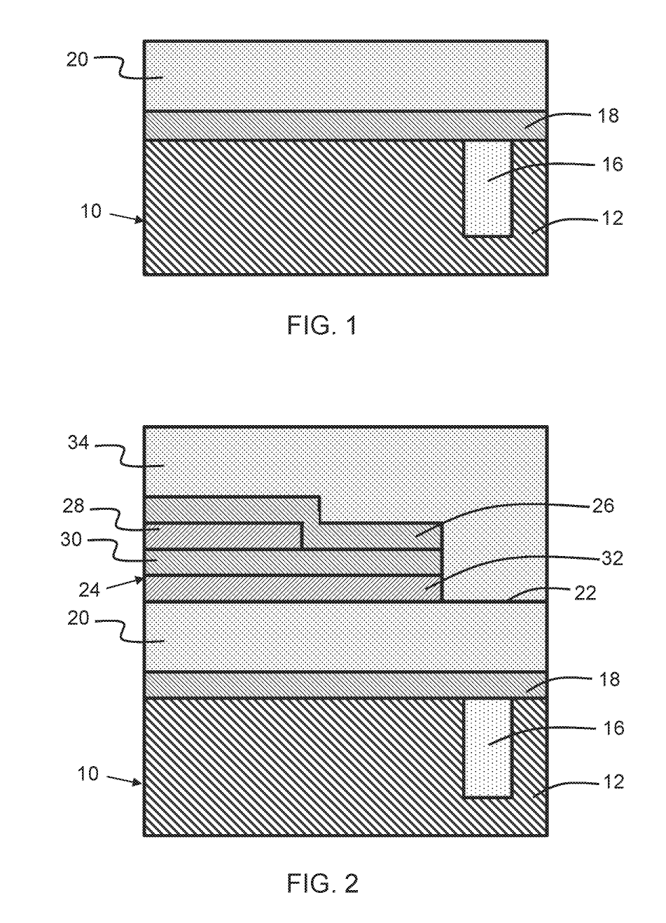

With reference to FIG. 1 and in accordance with embodiments of the invention, a back-end-of-line (BEOL) interconnect structure includes a dielectric layer 12 constituting an interlayer dielectric (ILD) of a metallization level 10, a conductive wiring feature 16 embedded in the dielectric layer 12, and a dielectric layer 18 on the dielectric layer 12. Additional metallization levels (not shown) may exist below the metallization level 10. The dielectric layer 12 may be comprised of an electrical insulator, such as an silicon dioxide (SiO₂). The dielectric layer 18 may be comprised of a nitride-based dielectric material. The conductive wiring feature 16 of the metallization level 10 may be comprised of a metal such as copper, aluminum, or an alloy of these metals. The BEOL interconnect structure, including the metallization level 10, is carried on a die or chip (not shown) that has been processed by front-end-of-line (FEOL) processes, such as a complementary metal-oxide-semiconductor (CMOS) process, to fabricate one or more integrated circuits that contain device structures. Conductive features in the different metallization levels function to interconnect devices of the integrated circuit and may provide circuit-to-circuit connections, or may establish contacts with input and output terminals.

A dielectric layer 20 is formed on the dielectric layer 18. In an embodiment, the dielectric layer 20 may be comprised of an organic polymeric material or polymer, such as a thermosetting polymer. In an embodiment, the dielectric layer 20 may be comprised of polyimide, which is chemically and thermally stabile, and which has a high mechanical strength. The dielectric layer 20 may be electrically insulating and, in that connection, may have a dielectric constant that is characteristic of a dielectric material. The dielectric layer 20 may be applied by spin-coating a poly(amic) acid solution onto the dielectric layer 18, and then curing at an elevated temperature (e.g., less than or equal to 400° C.) in an inert ambient. A thin layer of adhesion promoter, such as an organosilane, may be spin-coated on the top surface of the dielectric layer 18 before the dielectric layer 20 is formed on the dielectric layer 18.

With reference to FIG. 2 in which like reference numerals refer to like features in FIG. 1 and at a subsequent fabrication stage, a MIM capacitor 24 is formed on a top surface 22 of the dielectric layer 20. The MIM capacitor 24 includes a top electrode 28, a bottom electrode 32, and a capacitor dielectric 30 interposed vertically between the top electrode 28 and the bottom electrode 32. The electrodes 28, 32 may be comprised of one or more conductors, and the capacitor dielectric 30 may be composed of one or more dielectric materials. The capacitor dielectric 30 functions as an interplate dielectric layer that electrically insulates the top electrode 28 from the bottom electrode 32. The MIM capacitor 24 may be formed by patterning a layered stack of the constituent materials of the electrodes 28, 32 and capacitor dielectric 30 in one or more patterning processes. A protective layer 26 covers the MIM capacitor 24 and may be comprised of a dielectric material that is formed on the top surface of the MIM capacitor 24.

A dielectric layer 34, which is similar in composition to dielectric layer 20, is formed on the MIM capacitor 24 and dielectric layer 20 after the electrodes 28, 32 are patterned. In an embodiment, the dielectric layer 34 may be comprised of an organic polymeric material or polymer, such as a thermosetting polymer. In an embodiment, the dielectric layer 34 may be comprised of polyimide, which is chemically and thermally stabile, and which has a high mechanical strength. The dielectric layer 34 may be electrically insulating and, in that connection, may have a dielectric constant that is characteristic of a dielectric material. The dielectric layer 34 may be applied by spin-coating a poly(amic) acid solution onto the MIM capacitor 24 and dielectric layer 20, and then curing at an elevated temperature (e.g., less than or equal to 400° C.) in an inert ambient. A thin layer of adhesion promoter, such as an organosilane, may be spin-coated before the dielectric layer 34 is formed.

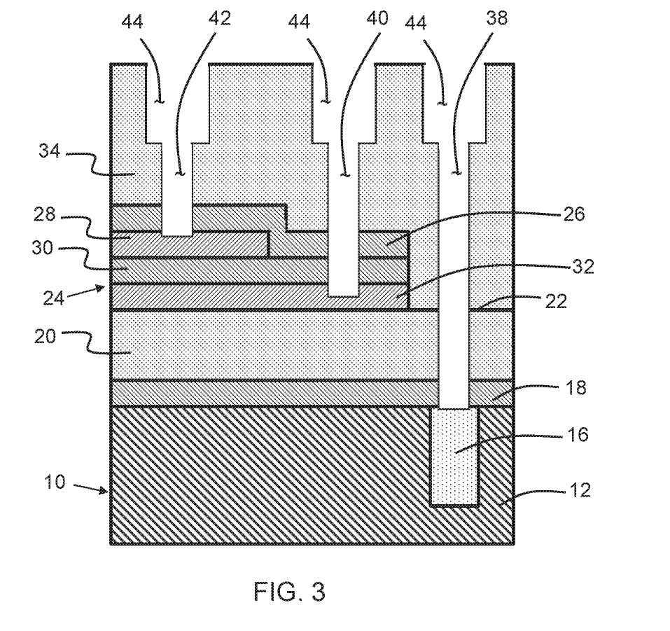

With reference to FIG. 3 in which like reference numerals refer to like features in FIG. 2 and at a subsequent fabrication stage, a patterned resist layer (not shown) may be applied on dielectric layer 34 and used to pattern vias 38, 40, 42 with an etching process, such as reactive ion etching (RIE). The etching process may be conducted in a single etching step with a given etch chemistry or in multiple etching steps with different etch chemistries. Via 38 extends in a vertical direction through the dielectric layer 34, dielectric layer 20, and dielectric layer 18 to the conductive wiring feature 16. Via 40 extends in the vertical direction through the dielectric layer 34 and capacitor dielectric 30 to the bottom electrode 32. Via 42 extends in the vertical direction through the dielectric layer 34, and protective layer 26 to the top electrode 28. A lithography and etch operation is used to form trenches 44 in the dielectric layer 34. Each of the trenches 44 may be aligned vertically with one of the vias 38, 40, 42.

The etching process that forms vertical sections of the vias 38, 40, 42 in the dielectric layer 34 and a vertical section of the via 38 in the dielectric layer 20 may rely on an etching process with high selectivity to the materials of the conductive wiring feature 16, top electrode 28, and bottom electrode 32. In an embodiment in which the dielectric layers 20, 34 are composed of polyimide, an oxygen-based etch using an O₂ plasma may be used to form the sections of the vias 38, 40, 42 in the dielectric layers 20, 34. In an alternative embodiment, a small amount of fluorine-containing gas may be added to the etching mixture.

Via 38 is required to be taller than either via 40 or via 42, which leads to the need to over-etch via 40 and via 42 in order to extend via 38 in the vertical direction to the conductive wiring feature 16. Because of the high selectivity of the etch process removing the organic polymeric material of the dielectric layers 20, 34, the vias 40 and 42 have a lower probability of respectively punching through the bottom electrode 32 or the top electrode 28 in comparison with conventional processes in which the dielectric layers 20, 34 are replaced by inorganic materials. In addition, the process margin for opening the vias 38, 40, 42 to the desired locations is improved.

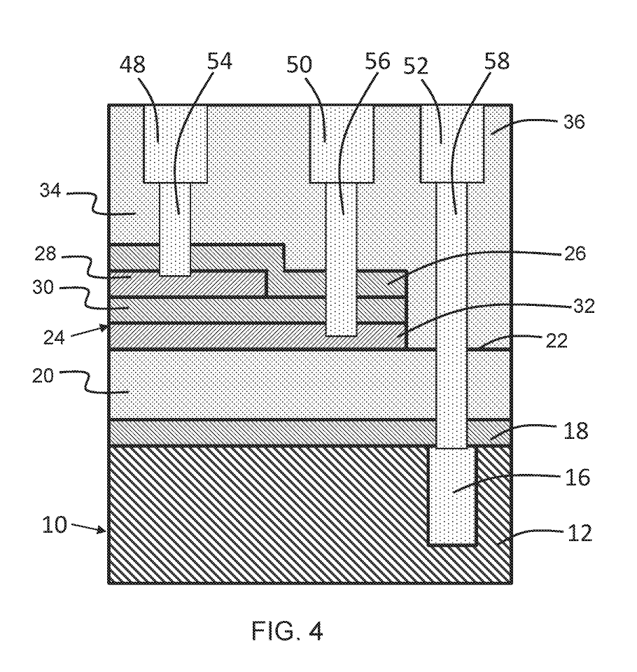

With reference to FIG. 4 in which like reference numerals refer to like features in FIG. 3 and at a subsequent fabrication stage, conductive lines 48, 50, 52 are formed as respective conductive wiring features in the open volumes inside the trenches 44, respectively, and conductive plugs 54, 56, 58 are formed as respective conductive wiring features in the open volumes inside the vias 38, 40, 42. Conductive lines 48, 50, 52 and conductive plugs 54, 56, 58 may be comprised of a conductor such as copper (Cu), aluminum (Al), a binary alloy such as AlCu, and other similar metals. The conductor may be formed by an electrochemical deposition process, such as electroplating or electroless plating.

A chemical-mechanical polishing (CMP) process may be used to remove excess liner material and conductor from the top surface of dielectric layer 34 and to planarize the conductive lines 48, 50, 52 to be flush with the top surface of dielectric layer 34. Conductive line 48 is electrically and physically connected by the conductive plug 54 with the top electrode 28. Conductive line 50 is electrically and physically connected by the conductive plug 56 with the bottom electrode 32. Conductive line 52 is electrically and physically connected by the conductive plug 58 with the conductive wiring feature 16 in dielectric layer 12.

The mechanical properties of the organic polymeric material (i.e., polymer) comprising the dielectric layer 20 and the dielectric layer 34 differ from the mechanical properties of inorganic dielectric materials, such as silicon dioxide (SiO₂) or silicon nitride (Si₃N₄). In particular, the polymer comprising the dielectric layers 20, 34 may exhibit a lower elastic modulus and a higher Poisson's ratio than inorganic dielectric materials so that the dielectric layers 20, 34 are comparatively softer and less rigid. As examples, silicon dioxide is characterized by an elastic modulus of 66-73 GPa and a Poisson's ratio of 0.17, silicon nitride is characterized by an elastic modulus of 200 to 310 GPa and a Poisson's Ratio of 0.27, and polyimide is characterized by an elastic modulus of 2.5 to 3.2 GPa and a Poisson's Ratio of 0.35. For these exemplary materials, the elastic modulus of polyimide is an order of magnitude smaller than the elastic modulus of either silicon dioxide or silicon nitride, and the Poisson's Ratio of polyimide is at least 30% larger than the Poisson's Ratio of either silicon dioxide or silicon nitride. As a result, the organic polymeric material constituting the dielectric layers 20, 34 may operate as a stress reliever in subsequent processing operations.

In addition, the organic polymeric material constituting the dielectric layers 20, 34 may have a lower dielectric constant than inorganic dielectric materials, such as silicon dioxide (SiO₂) or silicon nitride (Si₃N₄). For example, polyimide has a dielectric constant of 3.5, which is less than the dielectric constant (3.9 to 4.1) of silicon dioxide and the dielectric constant (9.5) of silicon nitride.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, “lateral”, etc. are made by way of example, and not by way of limitation, to establish a frame of reference. Terms such as “horizontal” and “lateral” refer to a direction in a plane parallel to a top surface of a semiconductor substrate, regardless of its actual three-dimensional spatial orientation. Terms such as “vertical” and “normal” refer to a direction perpendicular to the “horizontal” and “lateral” direction. Terms such as “above” and “below” indicate positioning of elements or structures relative to each other and/or to the top surface of the semiconductor substrate as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method comprising:
forming a first dielectric layer comprised of polyimide on a first electrode of a metal-insulator-metal capacitor;
etching a first via that extends vertically through the first dielectric layer to the first electrode using an oxygen-based plasma etch process; and
forming a first conductive plug in the first via that contacts the first electrode.

2-4. (canceled)

5. The method of claim 1 wherein the first electrode is located on a second dielectric layer comprised of polyimide, and further comprising:
forming a second via that extends vertically through the first dielectric layer and the second dielectric layer to a conductive wiring feature; and
forming a second conductive plug in the second via that contacts the conductive wiring feature.

6. The method of claim 5 wherein forming the second via that extends vertically through the first dielectric layer and the second dielectric layer to the conductive wiring feature comprises:
etching the second via using the oxygen-based plasma.

7. (canceled)

8. The method of claim 6 wherein the first via and the second via are concurrently etched with the oxygen-based plasma.

9. The method of claim 8 wherein the second via is taller than the first via.

10. (canceled)

11. The method of claim 1 wherein the metal-insulator-metal capacitor includes a second electrode and a capacitor dielectric, the capacitor dielectric is vertically positioned between the first electrode and the second electrode, the second electrode is located on a second dielectric layer comprised of polyimide, and the second electrode and the capacitor dielectric are vertically positioned between the first electrode and the second dielectric layer.

12-20. (canceled)
